(19) United States
(12) Patent Application Publication
(10) Pub. No.: US 2010/0167472 A1
(43) Pub. Date: Jul. 1, 2010

(54) IMPLANTATION SHADOWING EFFECT REDUCTION USING THERMAL BAKE PROCESS

(75) Inventors: Yiming Gu, PuDong New Area (CN); Shaofeng Yu, Plano, TX (US); James Blatchford, Richardson, TX (US)

Correspondence Address: TEXAS INSTRUMENTS INCORPORATED, P O BOX 655474, M/S 3999, DALLAS, TX, 75265, US

(73) Assignee: Texas Instruments Incorporated, Dallas, TX (US)

(21) Appl. No.: 12/646,479

(22) Filed: Dec. 23, 2009

Related U.S. Application Data
(60) Provisional application No. 61/141,533, filed on Dec. 30, 2008.

(51) Int. Cl. H01L 21/335; G03F 7/20

(52) U.S. Cl. 438/142; 430/319; 438/585; 438/669; 257/E21.023; 257/E21.4

(57) ABSTRACT

A method of forming a resist feature includes forming a resist layer over a semiconductor body, and selectively exposing the resist layer. The method further includes performing a first bake of the selectively exposed resist layer, and developing the selectively exposed resist layer to form a resist feature having a corner edge associated therewith, thereby exposing a portion of the semiconductor body. A second bake of the developed selectively exposed resist layer is then performed, thereby rounding the corner edge of the resist feature.

### REFERENCE TO RELATED APPLICATION

This application claims priority to and the benefit of U.S. Provisional Application Ser. No. 61/141,533 which was filed Dec. 30, 2008, entitled “IMPLANTATION SHADOWING EFFECT REDUCTION USING THERMAL BAKE PROCESS”, the entirety of which is hereby incorporated by reference as if fully set forth herein.

### FIELD OF INVENTION

The present invention relates generally to semiconductor devices and more particularly to a method of fabricating a resist structure and provides reduced shadowing during an implantation process.

### BACKGROUND OF THE INVENTION

There is a constant drive within the semiconductor industry to increase overall performance and operating speed of integrated circuit devices, e.g., microprocessors, memory devices, communication chips, and the like. This drive is fueled by consumer demands for computers and electronic devices that operate at increasingly greater speeds. This demand for increased speed has resulted in a continual reduction in the size of semiconductor devices and the components that make up such devices, e.g., transistors. That is, many features of a typical field effect transistor (FET), e.g., channel length, junction depth, gate dielectric thickness, and the like, are reduced. For example, all other things being equal, the smaller the channel length of the transistor, the faster the transistor will operate. Thus, there is a constant drive to reduce the size, or scale, of the components of a typical transistor to increase device performance and the overall speed of the transistor, as well as integrated circuit devices incorporating such transistors.

In addition, there is a constant drive to increase the density of modern integrated circuit devices, i.e., to put more and more semiconductor devices, e.g., transistors, closer together on a single chip. Increasing the density of integrated circuit devices makes more efficient use of the semiconductor die area, and may assist in increasing the overall yield from semiconductor manufacturing operations.

One problem encountered in efforts to increase the density of modern integrated circuit devices arises from limitations of the processes used to form halo or pocket implants in semiconductor devices. By way of background, halo or pocket implants are typically formed by implanting dopant atoms into the substrate at a non-perpendicular angle with respect to the surface of the substrate so as to result in a doped region that extends slightly under the gate dielectric of a typical MOS transistor. The dopant atoms used to form the halo or pocket implants will typically be comprised of the same type of dopant (N-type or P-type) as used to dope the underlying well or semiconductor body. For example, in the case of forming NMOS devices that typically reside in a p-type well, the halo or pocket implant will be comprised of a P-type dopant, e.g., boron. The purpose of the halo or pocket implant is to reduce the so-called short channel effects that are a result of device sizes being continually reduced. In particular, the halo or pocket implants are made in an effort to control or reduce the variations in the threshold voltage of an integrated circuit device due to variations in the channel length of the device. Despite a great effort, variations in the channel length of semiconductor devices are not uncommon. These variations occur due to a variety of reasons, e.g., manufacturing tolerances, implant variations, etc.

Many modem integrated circuit devices are comprised of both NMOS-type devices and PMOS-type devices, or a combination of both, e.g., CMOS technology. During the formation of these various halo or pocket implants, one of the types of devices, e.g., PMOS devices, must be covered or masked with a layer of material, such as photoresist, such that the dopant atoms are implanted only into the appropriate devices, i.e., the layer of photoresist keeps the dopant atoms from being implanted into unwanted active areas. However, since the halo or pocket implants are typically performed at an angle, e.g., 45 degrees, the height of the photoresist layer limits how close the devices of different construction, e.g., NMOS and PMOS devices, may be placed together. This, in turn, causes an undesirable consumption of die area on an integrated circuit device.

Prior art FIG. 1 illustrates a problem encountered in forming halo or pocket implants using a photoresist mask on a densely packed integrated circuit device. FIG. 1 depicts a partially-formed semiconductor device 10. The device 10 comprises NMOS and PMOS regions, respectively, wherein a p-well 14 resides in the NMOS region of a semiconductor body 15, and an n-well 16 resides in the PMOS region of the body, and wherein the active areas thereof are defined by isolation regions 18, such as field oxide regions (FOX), or shallow trench isolation (STI) regions. The transistors are comprised of a gate dielectric 20 formed above a surface of the semiconducting substrate 15, and a gate electrode 20 formed above the gate dielectric 20. The layer of photoresist 12 is formed above the gate electrode 22 and covers the PMOS region, thereby exposing the active area of the NMOS region to be subsequently implanted.

Still referring to FIG. 1, an opening 24 is formed in the photoresist layer 12 using traditional photolithographic techniques. The opening 24 has relatively vertical sidewalls and relatively sharp corners 26. The problem may arise when an angled implant process, such as that indicated by arrows 28, is performed in order to introduce dopant ions into the substrate under the gate dielectric 20. That is, given the relative height 30 of the photoresist layer 12, and the spacing between the sidewalls of the opening 24 and the sides of the gate electrode 22, the corner area 26 of the layer of photoresist 12 may act to prevent the ions from being implanted into the desired active area. This is known as shadowing. Prior techniques for combating this problem included spacing devices far enough apart such that the patterned layer of photoresist 12 does not block the dopant ions from the intended target. This type of solution, however, negatively affects die area.

### SUMMARY OF THE INVENTION

The following presents a simplified summary in order to provide a basic understanding of one or more aspects of the invention. This summary is not an extensive overview of the invention, and is neither intended to identify key or critical elements of the invention, nor to delineate the scope thereof. Rather, the primary purpose of the summary is to present some concepts of the invention in a simplified form as a prelude to the more detailed description that is presented later.

The present invention relates to a method of forming a resist feature that comprises forming a resist layer over a semiconductor body, and selectively exposing the resist layer. A first bake of the selectively exposed resist layer is then performed, followed by developing the selectively exposed resist layer to form a resist feature having a corner edge associated therewith, thereby exposing a portion of the semiconductor body. The method further comprises performing a second bake of the developed selectively exposed resist layer, thereby rounding the corner edge of the resist feature.

The present invention further relates to a method of forming a resist structure that comprises forming a chemical amplified deep ultraviolet resist layer over a semiconductor body surface, and patterning the resist layer to form a resist feature having a corner edge. The method further comprises rounding the corner edge of the resist structure with a bake process.

The present invention further relates to a method of forming a semiconductor device that comprises forming an active area of a first conductivity type within a semiconductor body of a second conductivity type. A gate structure is formed in the active area, and a resist layer is formed over the gate structure and the active area. The resist layer is then patterned to expose the gate structure and at least a portion of the active area, wherein the patterned resist layer has a corner edge associated therewith. The method further comprises rounding the corner edge of the patterned resist layer with a bake process, and implanting dopant at a non-perpendicular angle with respect to a surface of the active area into the exposed portion of the active area.

The following description and annexed drawings set forth in detail certain illustrative aspects and implementations of the invention. These are indicative of but a few of the various ways in which the principles of the invention may be employed.

### BRIEF DESCRIPTION OF THE DRAWINGS

FIG. 1 is a prior art fragmentary cross section diagram illustrating shadowing caused by a photoresist during an implantation process;

FIG. 2 is a flow chart illustrating a method of forming a photoresist feature according to one embodiment of the present invention;

FIGS. 3A-3F are fragmentary cross section diagrams illustrating various steps of forming a photoresist feature in accordance with the method of FIG. 2;

FIG. 4 is a diagram illustrating how photoresist corner rounding and associated photoresist trimming associated with the present invention results in reduced shadowing during a subsequent implantation process; and

FIG. 5 is a fragmentary cross section diagram illustrating an angled implant associated with a transistor having a patterned photoresist exhibiting corner rounding according to the method of FIG. 2.

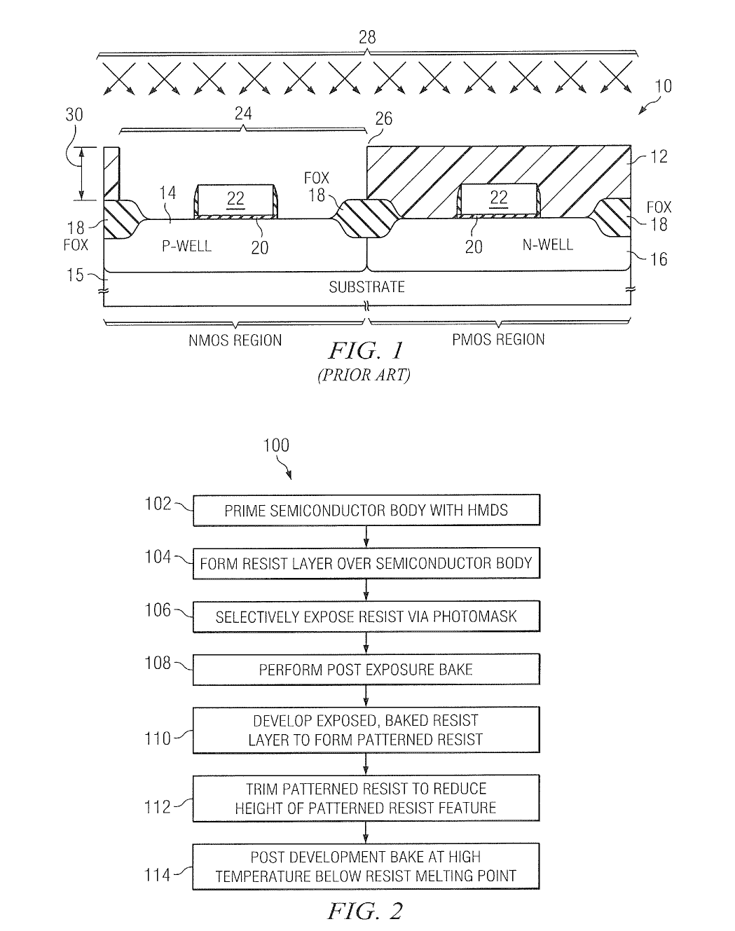

### DETAILED DESCRIPTION OF THE INVENTION

One or more implementations of the present invention will now be described with reference to the attached drawings, wherein like reference numerals are used to refer to like elements throughout, and wherein the illustrated structures are not necessarily drawn to scale. The present invention reduces shadowing by providing a rounding of a corner edge of a patterned photoresist by performing a high temperature bake of the patterned photoresist. The high temperature bake process is performed at a temperature that is greater than the post exposure bake performed prior to resist development, and at a temperature that is less than the melting point of the resist. The rounding of the corner edge of the resist reduces the amount of resist shadowing that occurs with angled implants, thus permitting layout spacing rules to be reduced, and consequently results in more densely packed devices.

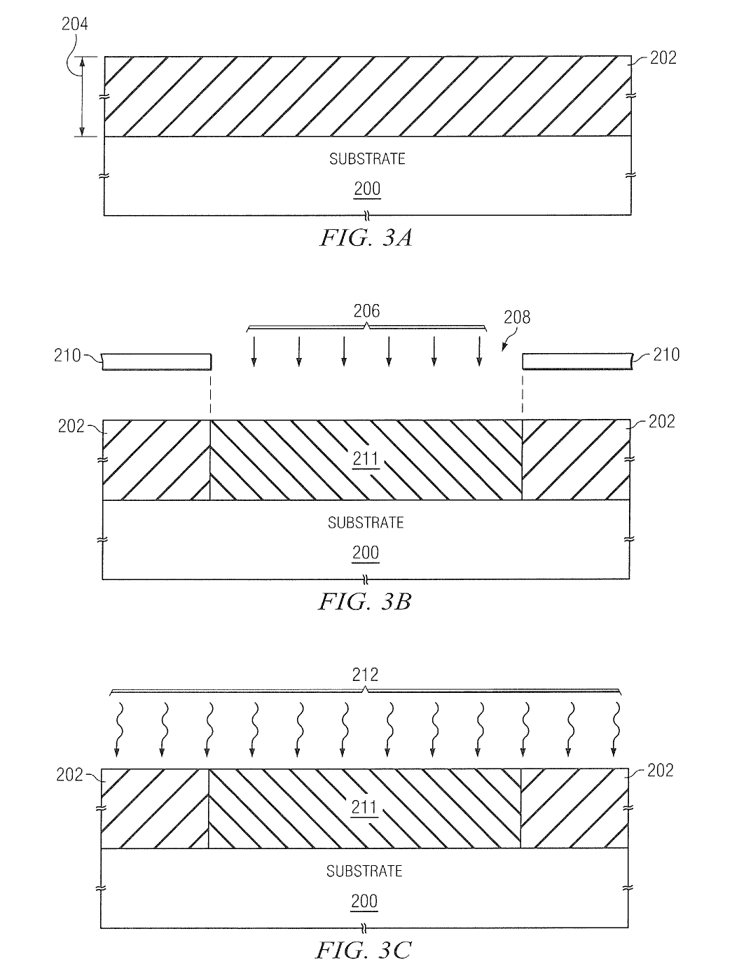

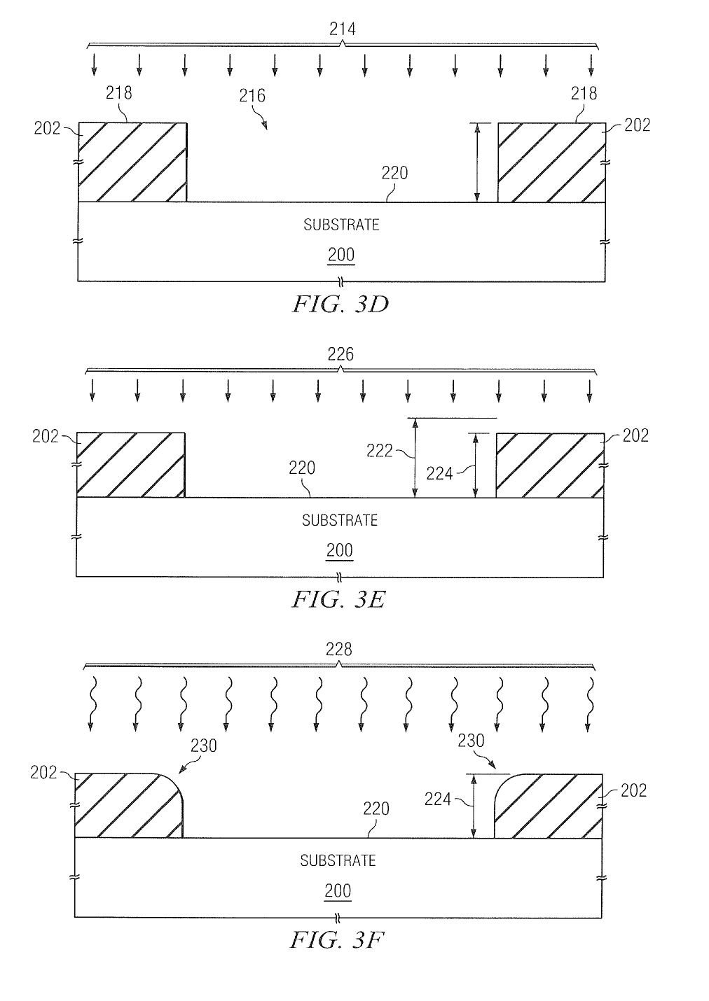

Turning now to the figures, FIG. 2 is a flow chart diagram illustrating a method 100 of forming a resist feature, and FIGS. 3A-3F are fragmentary cross section diagrams that illustrate resultant structures fabricated from the method 100. While the exemplary method 100 is illustrated and described below as a series of acts or events, it will be appreciated that the present invention is not limited by the illustrated ordering of such acts or events. For example, some acts may occur in different orders and/or concurrently with other acts or events apart from those illustrated and/or described herein, in accordance with the invention. In addition, not all illustrated steps may be required to implement a methodology in accordance with the present invention. Furthermore, the methods according to the present invention may be implemented in association with the fabrication of ICs and composite transistors illustrated and described herein, as well as in association with other transistors and structures not illustrated, including but not limited to NMOS and/or PMOS composite transistors, high Vt NMOS and high Vt PMOS transistors, low Vt NMOS and low Vt PMOS transistors, I/O NMOS and I/O PMOS transistors, etc.

The method 100 begins at 102 with an initial surface treatment of a surface of a semiconductor body 200. In one embodiment, the semiconductor body surface is treated with a primer to improve adhesion between the body 200 and a subsequently deposited resist layer. Many of the surfaces upon which a photoresist is to be formed oxidize relatively easily. The resultant surface oxide forms long range hydrogen bonds with water that is adsorbed from air. When the resist is subsequently formed on the body surface, it adheres to the water vapor rather than to the surface, resulting in poor adhesion. Accordingly, in one embodiment of the invention, a vapor phase primer such as hexamethyldisilazane (HMDS) is applied to the semiconductor body surface, for example, by a spin-coat process onto a dehydrated semiconductor workpiece. Alternatively, the HMDS is applied by a vapor priming process, wherein an HMDS vapor is brought into contact with the workpiece surface. The HMDS, or other primer material, serves as an adhesion promoter for the subsequently formed photoresist.

A resist layer 202 is then formed over the semiconductor body 200 at 104 of FIG. 2, as illustrated in FIG. 3A. In one embodiment the photoresist is a chemically amplified deep ultraviolet (DUV) resist for exposure at either 193 nm or 248 nm wavelengths. Any such resist may be employed, and all such alternatives are contemplated as falling within the scope of the present invention. In one embodiment the photoresist layer 202 is formed to a thickness 204 of about 1,500-2,500 Angstroms, although other thicknesses may be employed. In one embodiment the photoresist layer 202 is deposited by a spin-coat deposition process, however, any manner of resist deposition may be employed, and all such processes are contemplated as falling within the scope of the invention.

The method 100 of FIG. 2 continues at 106, wherein the photoresist layer 202 is selectively exposed to the appropriate ultraviolet radiation. In one embodiment, such selective exposure is illustrated in FIG. 3B, wherein ultraviolet radiation 206 passes through an opening 208 in a photomask 210 to expose a corresponding portion 211 of the photoresist layer 202.

Still referring to FIG. 2, the exposed photoresist layer 202 is then subjected to a post exposure bake 108, as illustrated at 212 of FIG. 3C. The post exposure bake (PEB) may serve multiple purposes. For example, the elevated temperature of the bake drives diffusion of the photoproducts, that can be helpful in minimizing the effects of standing waves, thereby improving critical dimension (CD) capability. In addition, the PEB may drive the acid-catalyzed reaction that alters the solubility of the polymer in many chemically amplified resists. Therefore the PEB makes the resist layer 202 more sensitive to a subsequent developer solution. In one embodiment, the PEB comprises subjecting the photoresist layer 202 to heat (e.g., in a thermal processing tool or chamber) of about 110° C. for about 1-2 minutes. Alternatively, other temperatures and durations may be employed, and all such variations are contemplated as falling within the scope of the invention.

After the post exposure bake, the exposed photoresist layer 202 is developed at 110 of FIG. 2, for example, by subjecting the layer to an aqueous alkali solution (e.g., 214 of FIG. 3D) that causes removal of the exposed portion at 216, while concurrently allowing the unexposed portions 218 to remain, in the cases of a positive resist. Any developer solution may be employed, and all such solutions and development processes are contemplated as falling within the scope of the invention. The result of developing process 214 results in a patterned photoresist layer, wherein underlying portions 220 of the semiconductor body 200 are exposed.

Referring again to FIG. 2, the patterned photoresist layer is then optionally subjected to a trim process at 112, wherein a height 222 of the photoresist layer is reduced to a second, shorter height 224, as illustrated in FIG. 3E. In one embodiment, the trim process comprises a dry etch process 226 that is selective to the underlying exposed semiconductor body 220. Alternatively, other forms of resist trimming that reduces the height may be employed, and all such processes are contemplated as falling within the scope of the present invention. In one embodiment of the invention, the initial photoresist layer height or thickness 222 is about 1,500-2,500 Angstroms, and the reduced height is approximately 1,000 Angstroms, however, such dimensions may vary and such variations are contemplated by the invention. In another embodiment of the invention, the photoresist trim process 112 of FIG. 2 is omitted.

The method 100 of FIG. 2 then proceeds to 114, wherein a post development bake process is performed, as illustrated at 228 of FIG. 3F. The post development bake process 228 causes the corner 230 at the edge of the patterned photoresist 202 to become rounded. As will be further appreciated, the rounding of the corner edge 230 results in decreased shadowing during any subsequent angled implantation process. In one embodiment the temperature of the post development bake is a high temperature that is near, but below the melting point of the resist. In one embodiment the post development bake is conducted at about 208° C. for about 90 seconds for a 193 nm photoresist, however, other temperatures near the melting point and other durations may be employed, and are contemplated as falling within the scope of the present invention.

FIG. 4 illustrates how the trim process 226 and the post exposure bake process 228 of the present invention reduce shadowing. For an original resist structure having an original height 222 (D), for an angled implant having an angle Θ with respect to a normal to the semiconductor body surface, an amount of shadowing R is equal to D·tan Θ. Similarly, for a trimmed resist having a reduced height 224 (D′), the shadowing is reduced to R′=D′tan Θ. Lastly, as can be seen in FIG. 4, the rounded corner edge 230 of the resist according to the invention results in a further “effective” reduction in the resist height 232 (D″) for a resultant shadowing amount of R″=D″tan Θ. This reduction is shadowing allows device layouts to be advantageously more compact. For example, not only is less extra space needed for halo or pocket implants, but less extra spacing is needed for well-to-gate spacing, TAP-to-gate, and HVT and LVT-to-gate spacings.

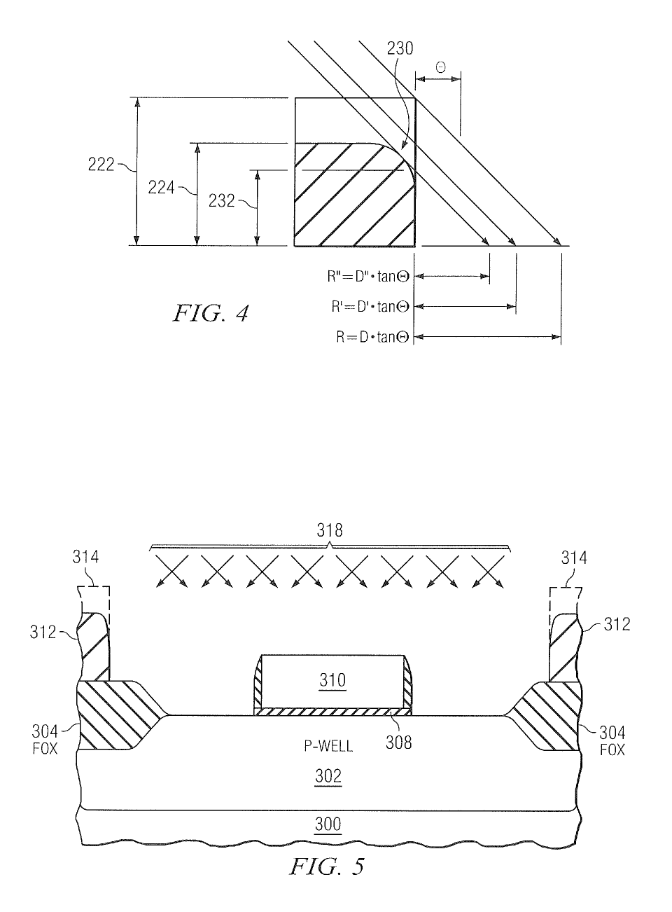

The corner rounding of a photoresist layer can be employed in conjunction with the formation of a transistor device, as illustrated in FIG. 5. A p-well region 302 resides in a p-type substrate 300. The p-well region 302 comprises an active area that is defined by isolation regions 304, such as field oxide regions (FOX), in one embodiment. A gate structure 306 comprises a gate dielectric 308 with a gate electrode 310 disposed thereover. To form a halo or pocket region in the active area, a photoresist layer 312 is formed over an n-well regions (not shown), wherein an edge of the photoresist layer 312 is illustrated in FIG. 5. In contrast to prior art resist processes that result in a feature 314 (illustrated in phantom), the method 100 of FIG. 2 may be employed to either solely round, or trim and round the photoresist layer to have a rounded edge 316, as illustrated in FIG. 5. The rounded edge 316 reduces an amount of shadowing during a subsequent angled implant process 318.

While FIG. 5 illustrates the benefit of the method 100 in conjunction with a halo or pocket implant, it should be understood that the method 100 may be employed in conjunction with other processing steps in the formation of a transistor device (either MOS or BJT), or in the fabrication of passive components, such as resistors, capacitors, etc. All such fabrications are contemplated as falling within the scope of the present invention.

While the invention has been illustrated and described with respect to one or more implementations, alterations and/or modifications may be made to the illustrated examples without departing from the spirit and scope of the appended claims. In particular regard to the various functions performed by the above described components or structures (assemblies, devices, circuits, systems, etc.), the terms (including a reference to a “means”) used to describe such components are intended to correspond, unless otherwise indicated, to any component or structure which performs the specified function of the described component (e.g., that is functionally equivalent), even though not structurally equivalent to the disclosed structure which performs the function in the herein illustrated exemplary implementations of the invention. In addition, while a particular feature of the invention may have been disclosed with respect to only one of several implementations, such feature may be combined with one or more other features of the other implementations as may be desired and advantageous for any given or particular application. Furthermore, to the extent that the terms “including”, “includes”, “having”, “has”, “with”, or variants thereof are used in either the detailed description and the claims, such terms are intended to be inclusive in a manner similar to the term “comprising”.

What is claimed is:

1. A method of forming a resist feature, comprising:
forming a resist layer over a semiconductor body;
selectively exposing the resist layer;
performing a first bake of the selectively exposed resist layer;
developing the selectively exposed resist layer to form a resist feature having a corner edge associated therewith, thereby exposing a portion of the semiconductor body;
performing a second bake of the developed selectively exposed resist layer, thereby rounding the corner edge of the resist feature.

2. The method of claim 1, wherein the resist layer has a melting point associated therewith, wherein a temperature of the second bake is less than the melting point of the resist coating.

3. The method of claim 2, wherein the temperature of the second bake is greater than a temperature of the first bake.

4. The method of claim 1, further comprising performing a trim process after developing the selectively exposed resist layer to reduce a height of the resist feature.

5. The method of claim 4, wherein the trim process is performed before the second bake.

6. The method of claim 1, further comprising performing a vapor phase priming of a surface of the semiconductor body prior to forming the resist layer thereon, thereby improving an adhesion of the resist layer to the semiconductor body surface.

7. A method of forming a resist structure, comprising:
forming a chemical amplified deep ultraviolet resist layer over a semiconductor body surface;
patterning the resist layer to form a resist feature having a corner edge; and
rounding the corner edge of the resist structure with a bake process.

8. The method of claim 7, further comprising performing a post-exposure bake process after the patterning of the resist layer.

9. The method of claim 8, wherein a temperature of the bake process employed to round the corner edge of the resist feature is greater than a temperature of the post-exposure bake process.

10. The method of claim 7, wherein a temperature of the bake process is less than the melting point of the resist layer.

11. The method of claim 7, further comprising performing a vapor phase priming of a surface of the semiconductor body prior to forming the resist layer thereon, thereby improving an adhesion of the resist layer to the semiconductor body surface.

12. The method of claim 7, further comprising performing a trim process after developing the selectively exposed resist layer to reduce a height of the resist feature.

13. The method of claim 12, wherein the trim process is performed before the bake process.

14. A method of forming a semiconductor device, comprising:
forming an active area of a first conductivity type within a semiconductor body of a second conductivity type;
forming a gate structure in the active area;
forming a resist layer over the gate structure and the active area;
patterning the resist layer to expose the gate structure and at least a portion of the active area, the patterned resist layer having a corner edge;
rounding the corner edge of the patterned resist layer with a bake process; and
implanting dopant at a non-perpendicular angle with respect to a surface of the active area into the exposed portion of the active area.

15. The method of claim 14, wherein the dopant is of the first conductivity type and forms a pocket implant region.

16. The method of claim 14, further comprising performing a trim process after developing the selectively exposed resist layer to reduce a height of the resist feature.

17. The method of claim 16, wherein the trim process is performed before the second bake.

18. The method of claim 14, wherein the resist layer has a melting point associated therewith, wherein a temperature of the second bake is less than the melting point of the resist coating.

19. The method of claim 14, further comprising performing a post-exposure bake process after the patterning of the resist layer.

20. The method of claim 19, wherein a temperature of the bake process employed to round the corner edge of the resist feature is greater than a temperature of the post-exposure bake process.
